(19) United States
(12) Patent Application Publication
(10) Pub. No.: US 2025/0194175 A1
(43) Pub. Date: Jun. 12, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Kaori FUSE, Yokohama Kanagawa (JP); Keiko KAWAMURA, Yokohama Kanagawa (JP); Takako MOTAI, Yokohama Kanagawa (JP)

(21) Appl. No.: 19/061,350

(22) Filed: Feb. 24, 2025

Related U.S. Application Data
(63) Continuation of application No. 17/470,168, filed on Sep. 9, 2021.

(30) Foreign Application Priority Data
Mar. 11, 2021 (JP) 2021-039109

(51) Int. Cl. H10D 62/10; H10D 12/00; H10D 30/68; H10D 62/60

(52) U.S. Cl. CPC H10D 62/107; H10D 12/441; H10D 30/6891; H10D 62/111; H10D 62/60

(57) ABSTRACT

A semiconductor device includes an element region and a termination region. The element region includes a first semiconductor region of a first conductivity type located on a first electrode and a second semiconductor region of a second conductivity type located on the first semiconductor region. The second semiconductor region is electrically connected with a second electrode. The termination region includes a third semiconductor region of the first conductivity type, a first diffusion layer of the second conductivity type located at a surface of the third semiconductor region, and a second diffusion layer of the second conductivity type. The third semiconductor region is located outward of the first semiconductor region. The first diffusion layer surrounds the element region. The second diffusion layer surrounds the element region, and is deeper than the first diffusion layer.

### CROSS-REFERENCE TO RELATED APPLICATIONS

This application is a continuation of U.S. patent application Ser. No. 17/470,168, filed on Sep. 9, 2021, which is based upon and claims the benefit of priority from Japanese Patent Application No. 2021-039109, filed on Mar. 11, 2021; the entire contents of each of which are incorporated herein by reference.

### FIELD

Embodiments relate to a semiconductor device.

### BACKGROUND

It is desirable to increase the reliability of a semiconductor device.

### BRIEF DESCRIPTION OF THE DRAWINGS

FIG. 1 is a cross-sectional view illustrating a semiconductor device according to a first embodiment;

FIGS. 2A and 2B are cross-sectional views illustrating models of semiconductor devices used in a simulation;

FIG. 3 is a graph illustrating simulation results of current-voltage characteristics of the semiconductor devices;

FIG. 4 is a cross-sectional view illustrating a semiconductor device according to a second embodiment;

FIGS. 5A and 5B are cross-sectional views illustrating models of semiconductor devices used in a simulation; and

FIG. 6 is a graph illustrating simulation results of current-voltage characteristics of the semiconductor devices.

### DETAILED DESCRIPTION

A semiconductor device according to one embodiment, includes an element region and a termination region. The element region includes a first semiconductor region and a second semiconductor region. The first semiconductor region is located on a first electrode. The first semiconductor region is of a first conductivity type. The second semiconductor region is located on the first semiconductor region. The second semiconductor region is of a second conductivity type and is electrically connected with a second electrode. The termination region includes a third semiconductor region, a first diffusion layer, and a second diffusion layer. The third semiconductor region is located outward of the first semiconductor region. The third semiconductor region is of the first conductivity type. The first diffusion layer is located at a surface of the third semiconductor region. The first diffusion layer is of the second conductivity type and surrounds the element region. The second diffusion layer is located at the surface of the third semiconductor region and is positioned further outward than the first diffusion layer. The second diffusion layer is of the second conductivity type, surrounds the element region, and is deeper than the first diffusion layer.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to an antecedent drawing are marked with like reference numerals, and a detailed description is omitted as appropriate.

In the following description and drawings, the notations of n⁺, n⁻, p⁺, and p indicate relative levels of the impurity concentrations. In other words, a notation marked with “+” indicates that the impurity concentration is relatively greater than that of a notation not marked with either “+” or “−”; and a notation marked with “−” indicates that the impurity concentration is relatively lower than that of a notation without any mark. When both a p-type impurity and an n-type impurity are included in each region, these notations indicate relative levels of the net impurity concentrations after the impurities are compensated.

In the embodiments described below, each embodiment may be implemented by inverting the p-type (an example of a second conductivity type) and the n-type (an example of a first conductivity type) of each semiconductor region.

### First Embodiment

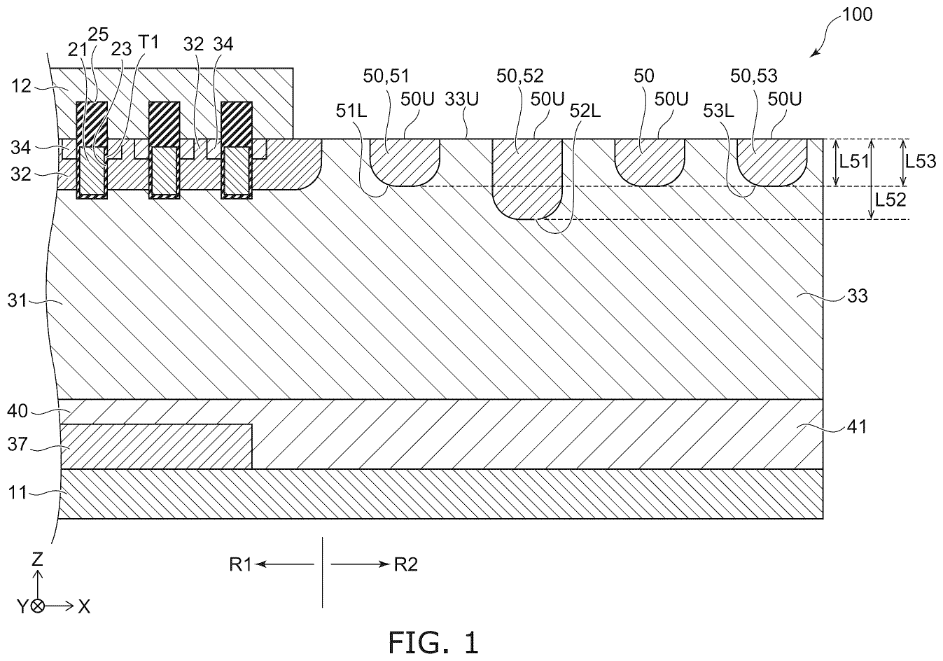

FIG. 1 is a cross-sectional view illustrating a semiconductor device according to a first embodiment.

FIG. 1 illustrates a cross section of a portion of the semiconductor device 100. The semiconductor device 100 includes a first electrode 11, a second electrode 12, an element region R1, and a termination region R2.

Here, the direction from the first electrode 11 toward the second electrode 12 is taken as a Z-direction (a first direction). Two mutually-orthogonal directions perpendicular to the Z-direction are taken as an X-direction and a Y-direction. In the description, the direction from the first electrode 11 toward the second electrode 12 is called “up”, and the opposite direction is called “down”. These directions are based on the relative positional relationship between the first electrode 11 and the second electrode 12, and are independent of the direction of gravity.

The element region R1 is a region in which an element such as a transistor or the like is located when viewed from above. In the example, an IGBT (Insulated Gate Bipolar Transistor) is located in the element region R1. However, the element that is located in the element region R1 is not limited to those described above. For example, the element that is located in the element region R1 may be a diode (e.g., a FRD (fast recovery diode), a reverse-conducting IGBT (Reverse-Conducting Insulated Gate Bipolar Transistor (RC-IGBT)), or a vertical power MOSFET (Metal Oxide Semiconductor Field Effect Transistor).

The termination region R2 is a region that is located outward of the element region R1 and surrounds the element region R1 when viewed from above. For example, the termination region R2 has a ring shape that surrounds four sides of the element region R1 without interruption. An element such as a transistor or the like is not provided in the termination region R2.

The element region R1 includes a collector region 37, a buffer region 40, a drift region 31 (a first semiconductor region), a base region 32 (a second semiconductor region), an emitter region 34 (a fourth semiconductor region), a gate electrode 21, and a gate insulating film 23.

For example, the first electrode 11 functions as the collector electrode of an IGBT. The collector region 37 is located on the first electrode 11 and is electrically connected with the first electrode 11. The collector region 37 is of the p⁺-type (the second conductivity type). The buffer region 40 is located on the collector region 37 and is of the n-type (the first conductivity type).

The drift region 31 is located on the buffer region 40 and is of the n⁻-type (the first conductivity type). The base region 32 is located on the drift region 31 and is of the p-type (the second conductivity type).

The emitter region 34 is located selectively on the base region 32 and is of the n⁺-type (the first conductivity type). The multiple emitter regions 34 are arranged in the X-direction; and each emitter region 34 extends in the Y-direction.

The gate electrode 21 faces a portion of the drift region 31, the base region 32, and a portion of the emitter region 34 via the gate insulating film 23. The multiple gate electrodes 21 are arranged in the X-direction; and each gate electrode 21 extends in the Y-direction.

In the example, multiple trench parts T1 are formed on the drift region 31. The multiple trench parts T1 are arranged in the X-direction; and each trench part T1 extends in the Y-direction. Each trench part T1 extends through the emitter region 34 and the base region 32 and reaches the drift region 31. An insulating portion 25 that includes the gate insulating film 23 is located in each trench part T1; and the gate electrodes 21 are located in the insulating portions.

The second electrode 12 is located on the base region 32, the emitter region 34, and the gate electrode 21 and is electrically connected with the base region 32 and the emitter region 34. For example, the second electrode 12 functions as the emitter electrode of an IGBT.

As described above, the element that is located in the element region R1 may be, for example, a diode. In such a case as well, the element region R1 includes an n-type first semiconductor layer that is located on the first electrode 11, and a p-type second semiconductor layer that is located on the first semiconductor layer and connected with the second electrode 12. For example, the first electrode 11 can be a cathode; and the second electrode 12 can be an anode.

The termination region R2 includes a semiconductor region 33 (a third semiconductor region) and multiple diffusion layers 50. The semiconductor region 33 is located on the first electrode 11 outward of the drift region 31, the base region 32, and the emitter region 34 of the element region R1. The semiconductor region 33 is a continuous region from the drift region 31 and is of the n⁻-type (the first conductivity type). The semiconductor region 33 is arranged with the drift region 31, the base region 32, and the emitter region 34 in a direction perpendicular to the Z-direction. For example, the semiconductor region 33 has a ring shape that surrounds four sides of the drift region 31, the base region 32, and the emitter region 34 without interruption when viewed from above.

A semiconductor region 41 may be located between the first electrode 11 and the semiconductor region 33. The semiconductor region 41 is, for example, a continuous region from the buffer region 40 and is of the n-type.

The diffusion layer 50 is a p-type semiconductor region that is located on the semiconductor region 33. The diffusion layer 50 extends from a front surface 33U (the upper surface) of the semiconductor region 33 into the semiconductor region 33. The diffusion layer 50 extends in the X-direction or the Y-direction and surrounds the element region R1 (the base region 32, the emitter region 34, and the gate electrode 21). For example, the diffusion layer 50 has a ring shape that surrounds four sides of the element region R1 without interruption when viewed from above. The diffusion layer 50 is a so-called guard ring.

The multiple diffusion layers 50 are separated from each other and are located in, for example, a concentric configuration. The spacing between adjacent diffusion layers 50 may be constant or may change. For example, the spacing between the adjacent diffusion layers 50 may increase outward in the semiconductor device. For example, the width (the length along the X-direction or the Y-direction) of the diffusion layer 50 is constant between the diffusion layers 50.

Four diffusion layers 50 are provided in the example.

However, according to the embodiment, the number of the diffusion layers 50 is not limited thereto, and may be two or more. It is desirable for the number of the diffusion layers 50 to be three or more, e.g., not less than about 3 and not more than about 10.

The multiple diffusion layers 50 include a first diffusion layer 51, a second diffusion layer 52, and a third diffusion layer 53. The first diffusion layer 51 is positioned further inward (toward the element region R1) than the second diffusion layer 52 and the third diffusion layer 53. In the example, among the multiple diffusion layers 50, the first diffusion layer 51 is the innermost diffusion layer 50. However, the first diffusion layer 51 may not be at the innermost side.

The second diffusion layer 52 is positioned further outward than the first diffusion layer 51. In the example, among the multiple diffusion layers 50, the second diffusion layer 52 is the second diffusion layer from the inner side. However, the second diffusion layer 52 may not be second from the inner side, and may not be adjacent to the first diffusion layer 51. For example, any number of diffusion layers 50 may be located between the first diffusion layer 51 and the second diffusion layer 52.

The third diffusion layer 53 is positioned further outward than the second diffusion layer 52. In the example, among the multiple diffusion layers 50, the third diffusion layer 53 is the outermost diffusion layer 50; and one diffusion layer 50 is located between the second diffusion layer 52 and the third diffusion layer 53. However, the third diffusion layer 53 may not be the outermost diffusion layer 50. Another diffusion layer 50 may not be provided between the second diffusion layer 52 and the third diffusion layer 53. In other words, the third diffusion layer 53 may be adjacent to the second diffusion layer 52. Any number of diffusion layers 50 may be located between the second diffusion layer 52 and the third diffusion layer 53.

The second diffusion layer 52 is deeper than the first diffusion layer 51. In other words, the Z-direction position of a lower end 52L of the second diffusion layer 52 is lower than the Z-direction position of a lower end 51L of the first diffusion layer 51. The level (the Z-direction position) of an upper end 50U is substantially the same between the multiple diffusion layers 50, and is the level of the front surface 33U of the semiconductor region 33.

The second diffusion layer 52 is deeper than the third diffusion layer 53. In other words, the Z-direction position of the lower end 52L of the second diffusion layer 52 is lower than the Z-direction position of a lower end 53L of the third diffusion layer 53.

The second diffusion layer 52 is, for example, the deepest diffusion layer 50 among the multiple diffusion layers 50. In other words, the Z-direction position of the lower end 52L of the second diffusion layer 52 is the lowest among the positions in the Z-direction of the lower ends of the multiple diffusion layers 50. Other than the second diffusion layer 52, the depths of the multiple diffusion layers 50 may be substantially the same.

For example, a length L51 along the Z-direction of the first diffusion layer 51 is not less than 1 μm and not more than 15 μm; a length L52 along the Z-direction of the second diffusion layer 52 is not less than 1.5 μm and not more than 40 μm; and a length L53 along the Z-direction of the third diffusion layer 53 is not less than 1 μm and not more than 15 μm.

For example, the difference between the length L51 and the length L52 is not less than 0.5 μm and not more than 25 μm. For example, the second diffusion layer 52 is deeper than the first diffusion layer 51 and the third diffusion layer 53 by not less than 0.5 μm. For example, the length L52 is not less than 1.5 times and not more than 40 times the length L51.

In each diffusion layer 50, the depth (the Z-direction position of the lower end) of the diffusion layer 50 is, for example, substantially constant over the entire perimeter that surrounds the element region R1. For example, the second diffusion layer 52 is deeper than the other diffusion layers 50 (e.g., the first diffusion layer 51 and the third diffusion layer 53) over the entire perimeter that surrounds the element region R1.

Examples of materials of the semiconductor device 100 will now be described.

The collector region 37, the buffer region 40, the drift region 31, the base region 32, the emitter region 34, the semiconductor region 41, the semiconductor region 33, and the diffusion layer 50 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity. For example, the regions and the diffusion layer 50 can be formed by ion-implanting impurities into a silicon semiconductor substrate.

The gate electrode 21 includes a conductive material such as polysilicon doped with an impurity, etc.

The gate insulating film 23 and the insulating portion 25 include an insulating material such as silicon oxide, etc.

The first electrode 11 and the second electrode 12 include, for example, a metal such as aluminum or the like that includes nickel, gold, or silicon.

Operations of the semiconductor device 100 will now be described.

A voltage that is not less than a threshold is applied to the gate electrode 21 in a state in which a voltage is applied between the first electrode 11 and the second electrode 12 so that the second electrode 12 is negative and the first electrode 11 is positive. Thereby, a channel (an inversion layer) is formed in the base region 32, and the IGBT is set to the on-state in the element region R1. Electrons flow from the second electrode 12 toward the drift region 31 via the emitter region 34 and the channel. Holes flow from the first electrode 11 toward the drift region 31 via the collector region 37. On the other hand, when the voltage that is applied to the gate electrode 21 drops below the threshold, the channel in the base region 32 disappears, and the IGBT is set to the off-state.

In the off-state, a positive voltage with respect to the diffusion layer 50 is applied to the first electrode 11. In other words, a reverse bias is applied to the p-n junction formed of the diffusion layer 50 and the semiconductor region 33. For example, the diffusion layer 50 is set to a ground potential. By providing the diffusion layer 50 at the front surface of the termination region R2, electric field concentration at the outer end portion of the element region R1 (i.e., in the example, the end portion of the base region 32) can be suppressed. Accordingly, the breakdown voltage of the semiconductor device 100 can be increased.

When an element other than an IGBT is provided in the element region R1 as well, a positive voltage with respect to the second electrode 12 and the diffusion layer 50 is applied to the first electrode 11 when the element is in the off-state. At this time, electric field concentration at the outer end portion of the element region R1 can be suppressed by the diffusion layer 50 at the front surface of the termination region R2.

Effects of the first embodiment will now be described.

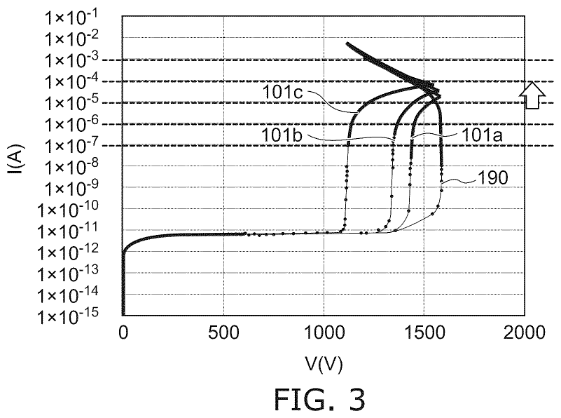

In the operation of the semiconductor device that includes multiple guard rings, when the voltage of the drain electrode with respect to the source electrode becomes large, there are cases where an electric field may concentrate at the lower end of one of the guard rings, and snapback (negative resistance) may occur. For example, as described below with reference to FIG. 3, snapback (negative resistance) is a phenomenon of the relationship between the current and the voltage in which voltage abruptly decreases as the current increases. There are cases where a large current flows and breakdown of the element occurs when snapback occurs. Conversely, according to the embodiment, the second diffusion layer 52 is deeper than the first diffusion layer 51. Thereby, when the voltage of the second electrode 12 with respect to the first electrode 11 becomes large, the current concentrates more easily at the second diffusion layer 52 than at the first diffusion layer 51. The first diffusion layer 51 is interposed between the second diffusion layer 52 and the element region R1; and the second diffusion layer 52 is separated from the element region R1; therefore, a horizontal-direction resistance component is generated in the current path of the large current. Therefore, negative resistance does not occur easily; and breakdown of the element does not occur easily. In other words, the reliability (the breakover immunity) of the element can be improved. This will now be described with reference to a simulation.

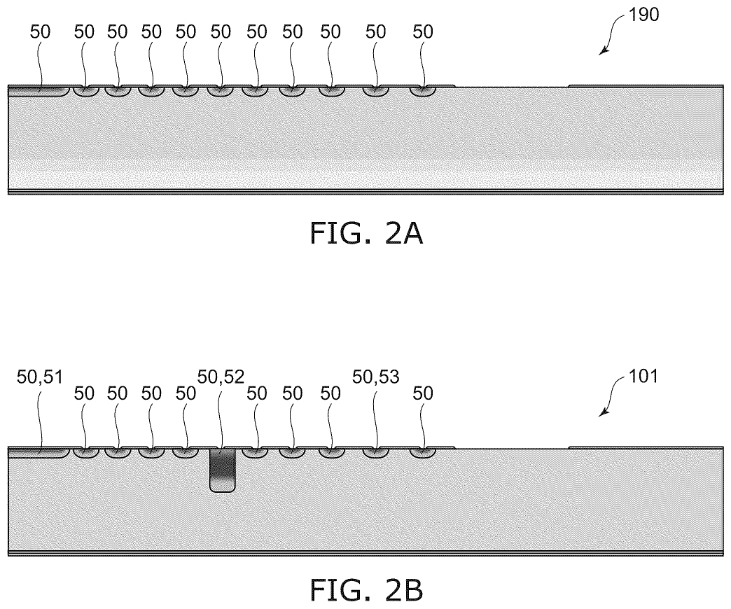

FIGS. 2A and 2B are cross-sectional views illustrating models of semiconductor devices used in the simulation.

FIG. 2A illustrates the termination region of a semiconductor device 190 according to a reference example. FIG. 2B illustrates the termination region of a semiconductor device 101 according to an example. In these drawings, the left side is the inner side (i.e., the element region side) of the semiconductor device; and the right side is the outer side of the semiconductor device. The element region is not illustrated.

In the semiconductor device 190 illustrated in FIG. 2A, the depths of the multiple diffusion layers 50 are the same. Otherwise, a description similar to that of the semiconductor device 100 described with reference to FIG. 1 is applicable to the semiconductor device 190. In the example, the number of the diffusion layers 50 is 11. The diffusion layer 50 that is most proximate to the left side in the drawing is the innermost diffusion layer 50 (toward the element region R1) among the multiple diffusion layers 50. The impurity concentrations of the multiple diffusion layers 50 are substantially the same and are, for example, about 1×10¹⁶ cm⁻³.

In the semiconductor device 101 illustrated in FIG. 2B, the second diffusion layer 52 is deeper than the first diffusion layer 51 and the third diffusion layer 53. More specifically, among the multiple diffusion layers 50, only the second diffusion layer 52 is formed to be deep; and the depths of the other diffusion layers 50 are the same. Otherwise, the semiconductor device 101 is similar to the semiconductor device 190.

In the simulation, the second electrode 12 is set to 0 V; the diffusion layer 50 is floating (a floating potential); and a positive voltage is applied to the first electrode 11. The electric field intensity, the probability of impact ionization occurring, the current density, the current flowing in the first electrode 11, etc., for the termination region R2 were calculated. In the semiconductor device 190 of the reference example, the electric field intensity, the impact ionization rate, and the current density were high for the innermost diffusion layer 50 among the multiple diffusion layers 50. Conversely, in the semiconductor device 101 of the example, among the multiple diffusion layers 50, the electric field intensity, the impact ionization rate, and the current density of the second diffusion layer 52 were greater than those of the other diffusion layers 50. According to the example, the current can be concentrated in the second diffusion layer 52.

FIG. 3 is a graph illustrating simulation results of the current-voltage characteristics of the semiconductor devices. In FIG. 3, the horizontal axis corresponds to a voltage V (V) of the first electrode 11, and the vertical axis corresponds to a current I (A). FIG. 3 shows I-V characteristics of the semiconductor devices 190, 101a, 101b, and 101c. The semiconductor devices 101a, 101b, and 101c are semiconductor devices that are similar to the semiconductor device 101 shown in FIG. 2B. In the semiconductor device 101a, the depth of the second diffusion layer 52 is 30 μm; and the impurity concentration of the second diffusion layer 52 is 1×10¹⁶ cm⁻³. In the semiconductor device 101b, the depth of the second diffusion layer 52 is 40 μm; and the impurity concentration of the second diffusion layer 52 is 1×10¹⁶ cm⁻³. In the semiconductor device 101c, the depth of the second diffusion layer 52 is 40 μm; and the impurity concentration of the second diffusion layer 52 is 1×10²⁰ cm⁻³.

In the semiconductor device 190, the current value increases when the voltage is about 1600 V; and a flexion point appears in the I-V characteristic when the current is about 1×10⁻⁵ (A). In other words, negative resistance occurs when the 5 current exceeds about 1×10⁻⁵ (A).

In the semiconductor device 101a, the current value increases when the voltage is about 1430 V. As the voltage further increases, a flexion point appears in the I-V characteristic when the current is about 2×10⁻⁵ (A). In other words, negative resistance occurs when the current exceeds about 2×10⁻⁵ (A). In the semiconductor device 101b, the current value increases when the voltage is about 1430 V. As the voltage further increases, a flexion point appears in the I-V characteristic when the current is about 3×10⁻⁵ (A). In other words, negative resistance occurs when the current exceeds about 3×10⁻⁵ (A).

In the semiconductor device 101c, the current value increases when the voltage is about 1100 V. As the voltage further increases, a flexion point appears in the I-V characteristic when the current is about 8×10⁻⁵ (A). In other words, negative resistance occurs when the current exceeds about 8×10⁻⁵ (A).

Thus, the current values at which the negative resistance occurs in the semiconductor devices 101a, 101b, and 101c according to the examples are greater than the current value at which the negative resistance occurs in the semiconductor device 190 according to the reference example. In other words, negative resistance occurs less easily in the examples than in the reference example. Therefore, breakdown of the semiconductor device does not occur easily, and the reliability (the breakover immunity) can be improved.

For example, when snapback occurs in the turned-off state of an IGBT, the current concentrates in one of the guard rings; and a large current flows in the vertical direction from the collector electrode toward that guard ring. In such a state in which snapback has occurred, there are cases where the breakover immunity is insufficient, and breakdown of the element may occur. Conversely, according to the embodiment, the current value (the flexion point) at which snapback occurs can be increased. The breakover immunity is improved thereby, and breakdown does not occur easily.

For example, when the voltage of the first electrode 11 becomes large, a hole current flows due to holes from the backside (the lower side) and/or from impact ionization; and the density of the holes becomes high at the vicinity of the p-n junction at the front side (the upper side). At the front side of the element, it is estimated that negative resistance occurs when the concentrated holes flow toward the second electrode 12 side of the element region R1; and breakdown of the element occurs.

Here, in the semiconductor device 190 of the reference example as described above, the current concentrates at the diffusion layer 50 most proximate to the element region side among the multiple diffusion layers 50. On the other hand, in the semiconductor device 101 of the example, the current concentrates at the second diffusion layer 52 that is further outward than the first diffusion layer 51 in the semiconductor device 101 of the example. In other words, the position at which the current concentrates is more distant to the element region in the example than in the reference example. Because the current concentrates at a position that is separated from the element region, the path of the current that flows from the concentration position of the current along the front surface of the termination region toward the element region is longer. It is estimated that the resistance component of the current path toward the element region at the front surface of the termination region is increased thereby, and negative resistance does not occur easily.

In the semiconductor device, there is a risk that fluctuation of the position, depth, impurity concentration, etc., of the diffusion layer may occur due to fluctuation of the manufacturing processes. For example, a location at which the resistance is low occurs due to fluctuation such as diffusion fluctuation, etc.; and the current concentrates at this location. Due to fluctuation of the manufacturing processes, there is a risk that fluctuation of the ease of occurrence of negative resistance may occur, and the reliability (the breakover immunity) may decrease. Conversely, according to the embodiment, by providing the second diffusion layer 52 that is deeper than the first diffusion layer 51, the location at which the current easily concentrates can be limited. The effects of fluctuation of the manufacturing processes can be suppressed thereby, and the reliability can be increased. In the semiconductor device 101, the reliability can be further increased by concentrating the current at a fixed position (the position of the deepest second diffusion layer 52).

Also, according to the embodiment, the second diffusion layer 52 is deeper than the third diffusion layer 53. That is, the third diffusion layer 53 that is shallower than the second diffusion layer 52 is located outward of the second diffusion layer 52 that is relatively deep and is where the current easily concentrates. The effects of external charge can be suppressed thereby.

### Second Embodiment

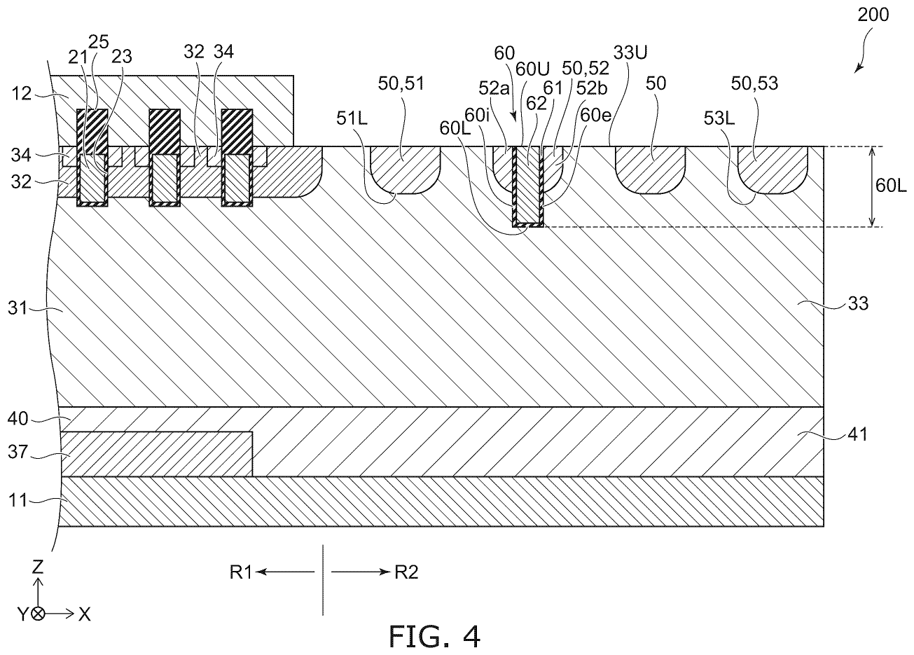

FIG. 4 is a cross-sectional view illustrating a semiconductor device according to a second embodiment.

FIG. 4 illustrates a cross section of a portion of the semiconductor device 200. The semiconductor device 200 also includes the first electrode 11, the second electrode 12, the element region R1, and the termination region R2. The semiconductor device 200 further includes a trench part 60. In the semiconductor device 200, the depth of the second diffusion layer 52 may be substantially equal to the depth of the first diffusion layer 51. Otherwise, a description similar to that of the semiconductor device 100 is applicable to the semiconductor device 200.

The trench part 60 is a recess provided in the front surface 33U of the semiconductor region 33. The trench part 60 extends downward from the front surface 33U of the semiconductor region 33. The trench part 60 contacts the second diffusion layer 52.

The trench part 60 is deeper than the first diffusion layer 51 and the third diffusion layer 53. In other words, the Z-direction position of a lower end 60L of the trench part 60 is lower than the Z-direction position of the lower end 51L of the first diffusion layer 51 and lower than the Z-direction position of the lower end 53L of the third diffusion layer 53.

The level (the Z-direction position) of an upper end 60U of the trench part 60 is the level of the front surface 33U of the semiconductor region 33. A length L60 along the Z-direction of the trench part 60 is, for example, not less than 1.5 μm and not more than 40 μm.

The trench part 60 also extends in the X-direction or the Y-direction. For example, the trench part 60 is located along the guard ring and surrounds the element region R1 (the base region 32, the emitter region 34, and the gate electrode 21) when viewed from above. For example, the trench part 60 has a ring shape that surrounds four sides of the element region R1 without interruption when viewed from above.

However, according to the embodiment, the trench part 60 may have a shape that discontinuously surrounds the element region R1. In other words, the scope of “the trench part 60 surrounds the element region R1” also includes a case where a portion of the ring shape is interrupted, and a case where the trench part 60 is subdivided into multiple portions that are separated from each other, and the multiple portions are arranged around the element region R1. The trench part 60 can be considered to surround the element region when the element region R1 is positioned inward of a trajectory tracing the components of the trench part 60. The trench part 60 may not always surround the element region R1.

In the example, the trench part 60 extends through the second diffusion layer 52. An inner side surface 60i and an outer side surface 60e of the trench part 60 each contact the second diffusion layer 52. The second diffusion layer 52 may be divided into an inner portion 52a and an outer portion 52b by the trench part 60.

The termination region R2 further includes an insulating portion 61 that is located inside the trench part 60. The insulating portion 61 is filled into the trench part 60 and contacts the second diffusion layer 52 and the semiconductor region 33.

The termination region R2 further includes a conductive portion 62 that is located inside the trench part 60. The conductive portion 62 is filled into the trench part 60 and the insulating portion 61 and is electrically insulated from the semiconductor region 33 and the diffusion layer 50 by the insulating portion 61. That is, the insulating portion 61 is located between the conductive portion 62 and the semiconductor region 33 and between the conductive portion 62 and the diffusion layer 50 and covers the lower surface and side surface of the conductive portion 62. Thereby, the conductive portion 62 does not contact the semiconductor region 33 and the diffusion layer 50. The conductive portion 62 may not always be provided.

Examples of materials of the semiconductor device 200 will now be described.

The insulating portion 61 includes an insulating material such as silicon oxide, silicon nitride, etc.

The conductive portion 62 includes a conductive material such as polysilicon doped with an impurity, etc. The conductive portion 62 may include, for example, a metal such as aluminum or the like that includes nickel, gold, or silicon. When operating the element, for example, the conductive portion 62 is set to be floating.

Effects of the second embodiment will now be described.

The second embodiment includes the trench part 60 that contacts the second diffusion layer 52 that is deeper than the first diffusion layer 51. Thereby, when the voltage of the second electrode 12 with respect to the first electrode 11 becomes large, the current concentrates more easily in the trench part 60 than in the first diffusion layer 51; negative resistance does not occur easily; and breakdown of the element does not occur easily. These effects will now be described with reference to a simulation.

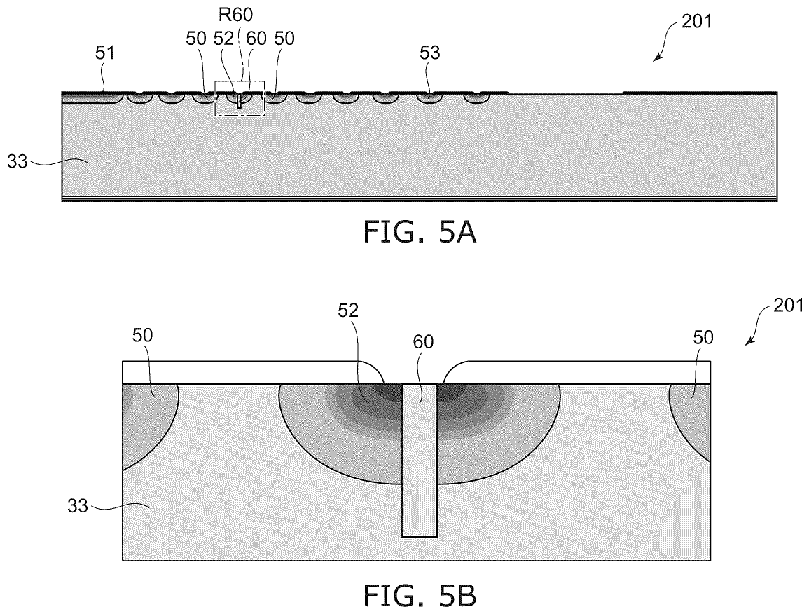

FIGS. 5A and 5B are cross-sectional views illustrating models of semiconductor devices used in the simulation.

FIG. 5A illustrates the termination region of a semiconductor device 201 according to an example. In the drawing, the left side is the inner side (i.e., the element region side) of the semiconductor device; and the right side is the outer side of the semiconductor device. The element region is not illustrated. FIG. 5B is an enlarged view of region R60 shown in FIG. 5A. The semiconductor device 201 includes the trench part 60 that contacts the second diffusion layer 52 that is deeper than the first diffusion layer 51. Otherwise, the semiconductor device 201 is similar to the semiconductor device 190 described with reference to FIG. 2A.

In the simulation, the second electrode 12 is set to 0 V; the diffusion layer 50 is set to be floating; and a positive voltage is applied to the first electrode 11. The electric field intensity, the probability of impact ionization occurring, the current density, the current flowing in the first electrode 11, etc., for the termination region R2 were calculated.

In the semiconductor device 201 of the example, the electric field intensity, the impact ionization rate, and the current density are higher at the trench part 60 (the second diffusion layer 52) than at the other diffusion layers 50. It is considered that the current flows from the first electrode 11 along the surfaces of the semiconductor region 33 and the trench part 60, passes through the second diffusion layer 52, and flows toward the front surface of the termination region R2. According to the example, the current can be concentrated in the trench part 60 (the second diffusion layer 52).

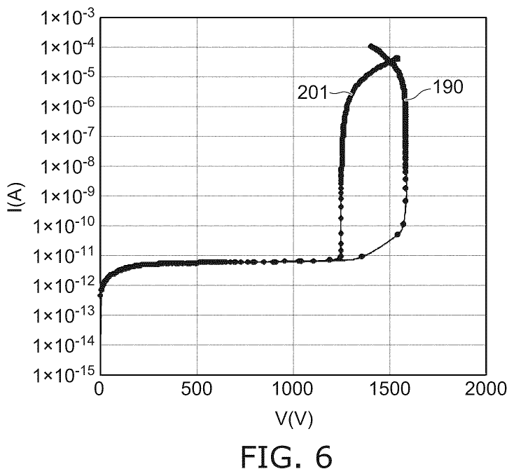

FIG. 6 is a graph illustrating a simulation of current-voltage characteristics of the semiconductor devices. In FIG. 6, the horizontal axis corresponds to the voltage V (V) of the first electrode 11, and the vertical axis corresponds to the current I (A). FIG. 6 shows the I-V characteristics of the semiconductor devices 190 and 201.

In the semiconductor device 201, the current value increases when the voltage is about 1250 V. As the voltage further increases, negative resistance does not appear even when the current value exceeds 4×10⁻⁵ (A). On the other hand, in the semiconductor device 190 of the reference example, negative resistance occurs when the current exceeds about 1×10⁻⁵ (A). In other words, negative resistance occurs less easily in the example than in the reference example. Thereby, breakdown of the semiconductor device does not occur easily, and the reliability (the breakover immunity) can be improved.

In the semiconductor device 201 of the example, the current concentrates in the trench part 60 (the second diffusion layer 52) that is further outward than the first diffusion layer 51. In other words, compared to the reference example, the current concentrates at a position that is distant to the element region in the example. Similarly to the first embodiment, it is estimated that the resistance component of the current path toward the element region at the front surface of the termination region is increased thereby, and negative resistance does not occur easily.

According to the embodiment, the location at which the current easily concentrates can be limited by providing the trench part 60. Similarly to the first embodiment, the effects of fluctuation of the manufacturing processes can be suppressed thereby, and the reliability can be increased.

Multiple trench parts 60 can be provided. For example, the multiple trench parts 60 may be arranged from the inner side (the element region R1 side) toward the outer side. For example, a first trench part and a second trench part that is positioned further outward than the first trench part and surrounds the first trench part may be provided. However, when the number of the trench parts 60 is 1, the current easily concentrates at a fixed position (the position at which the one trench part 60 is located).

The trench part 60 is deeper than the third diffusion layer 53. Similarly to the first embodiment, the effects of external charge can be suppressed thereby.

It is desirable for the trench part 60 to extend through the second diffusion layer 52. By surrounding the trench part 60 with the second diffusion layer 52 that is a current path, the current can be more easily concentrated at the trench part 60, and the negative resistance is more easily suppressed.

It is desirable for the trench part 60 to surround the element region R1 when viewed from above. Thereby, the current can be easily concentrated at the trench part 60 over substantially the entire perimeter of the semiconductor device; and negative resistance is more easily suppressed.

The insulating portion 61 is located in the trench part 60. The conductive portion 62 that includes polysilicon or a metal also may be provided in the trench part 60. In such a case, the trench part 60, the insulating portion 61, and the conductive portion 62 may be formed using a process for forming a portion of the element region R1 (e.g., a formation process of the trench gate). Thereby, the manufacturing processes can be simple, and an increase of the manufacturing cost can be suppressed. The conductive portion 62 may be floating. The manufacturing processes can be simple because an electrode or interconnect for controlling the potential of the conductive portion 62 may not be provided.

According to embodiments, a semiconductor device can be provided in which the reliability can be increased.

The relative levels of the impurity concentrations between the semiconductor regions in each of the embodiments described above can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region also can be measured by, for example, SIMS (secondary ion mass spectrometry).

In this specification, being “electrically connected” includes not only the case of being connected in direct contact, but also the case of being connected via another conductive member, etc.

Hereinabove, exemplary embodiments of the invention are described with reference to specific examples. However, the invention is not limited to these specific examples. For example, various modifications made by one skilled in the art in regard to the configurations, sizes, material qualities, arrangements, etc., of components of semiconductor devices are included in the scope of the invention to the extent that the purport of the invention is included.

Furthermore, any two or more components of the specific examples may be combined within the extent of technical feasibility, and are included in the scope of the invention to the extent that the purport of the invention is included.

Moreover, all semiconductor devices practicable by an appropriate design modification by one skilled in the art based on the semiconductor devices described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
an element region including
a first semiconductor region located on a first electrode, the first semiconductor region being of a first conductivity type, and
a second semiconductor region located on the first semiconductor region, the second semiconductor region being of a second conductivity type and being electrically connected with a second electrode; and
a termination region including
a third semiconductor region located outward of the first semiconductor region, the third semiconductor region being of the first conductivity type, and
a plurality of diffusion layers located at a surface of the third semiconductor region, each of the diffusion layers being of the second conductivity type and surrounding the element region, the diffusion layers including a first diffusion layer, a second diffusion layer positioned further outward than the first diffusion layer with respect to the second semiconductor region, a third diffusion layer positioned further outward than the second diffusion layer with respect to the second semiconductor region, and a fourth diffusion layer positioned between the second diffusion layer and the third diffusion layer, the second diffusion layer being deeper than each of the diffusion layers other than the second diffusion layer, each of the diffusion layers other than the second diffusion layer having a same depth, a width of the third semiconductor region between adjacent two of the diffusion layers increasing outward of the semiconductor device,
wherein the semiconductor device has an electric field characteristic that with application of a positive voltage with respect a voltage of the second electrode to the first electrode, an electric field intensity in the second diffusion layer becomes higher than an electric field intensity in each of the diffusion layers other than the second diffusion layer.

2. The device according to claim 1, wherein
the element region further includes:
a fourth semiconductor region located on the second semiconductor region, the fourth semiconductor region being of the first conductivity type; and
a gate electrode facing the second semiconductor region via a gate insulating film,
the second electrode is located on the second semiconductor region, the fourth semiconductor region, and the gate electrode, and
the second electrode is electrically connected with the second and fourth semiconductor regions.

3. The device according to claim 1, wherein a depth of the second diffusion layer is equal to or greater than 1.5 times a depth of each of the diffusion layers other than the second diffusion layer, and equal to or less than 40 times the depth of each of the diffusion layers other than the second diffusion layer.

4. A semiconductor device, comprising:
an element region including
a first semiconductor region located on a first electrode, the first semiconductor region being of a first conductivity type, and
a second semiconductor region located on the first semiconductor region, the second semiconductor region being of a second conductivity type and being electrically connected with a second electrode; and
a termination region including
a third semiconductor region located outward of the first semiconductor region, the third semiconductor region being of the first conductivity type,
a plurality of diffusion layers located at a surface of the third semiconductor region, each of the diffusion layers being of the second conductivity type and surrounding the element region, the diffusion layers including a first diffusion layer, a second diffusion layer positioned further outward than the first diffusion layer with respect to the second semiconductor region, a third diffusion layer positioned further outward than the second diffusion layer with respect to the second semiconductor region, and a fourth diffusion layer positioned between the second diffusion layer and the third diffusion layer, the second diffusion layer being deeper than each of the diffusion layers other than the second diffusion layer, each of the diffusion layers other than the second diffusion layer having a same depth, a width of the third semiconductor region between adjacent two of the diffusion layers increasing outward of the semiconductor device, and
a trench part located at the surface of the third semiconductor region, the trench part contacting the second diffusion layer and being deeper than the first diffusion layer,
wherein the semiconductor device has an electric field characteristic that with application of a positive voltage with respect a voltage of the second electrode to the first electrode, an electric field intensity in the second diffusion layer becomes higher than an electric field intensity in each of the diffusion layers other than the second diffusion layer.

5. The device according to claim 4, wherein
the trench part extends through the second diffusion layer.

6. The device according to claim 4, wherein
the trench part surrounds the element region.

7. The device according to claim 4, wherein
the trench part is deeper than the third diffusion layer.

8. The device according to claim 4, wherein
the termination region includes an insulating portion located inside the trench part.

9. The device according to claim 8, wherein
the termination region includes a conductive portion located inside the trench part, and
the conductive portion is electrically insulated from the third semiconductor region by the insulating portion.

10. The device according to claim 9, wherein
a potential of the conductive portion is floating.

11. The device according to claim 9, wherein
a material of the conductive portion includes at least one of polysilicon or a metal.

12. The device according to claim 4, wherein
the element region further includes:
a fourth semiconductor region located on the second semiconductor region, the fourth semiconductor region being of the first conductivity type; and
a gate electrode facing the second semiconductor region via a gate insulating film,
the second electrode is located on the second semiconductor region, the fourth semiconductor region, and the gate electrode, and
the second electrode is electrically connected with the second and fourth semiconductor regions.
